(19) United States
(12) Patent Application Publication
(10) Pub. No.: US 2004/0031996 A1
(43) Pub. Date: Feb. 19, 2004

(54) Semiconductor device and method for forming

(76) Inventors: Chi Nan Brian Li, Austin, TX (US); Didier Farenc, Austin, TX (US); Kuo-Tung Chang, Saratoga, CA (US)

Correspondence Address: MOTOROLA INC, AUSTIN INTELLECTUAL PROPERTY, LAW SECTION, 7700 WEST PARMER LANE MD: TX32/PL02, AUSTIN, TX, 78729

(21) Appl. No.: 10/222,688

(22) Filed: Aug. 16, 2002

(51) Int. Cl. H01L 29/76

(52) U.S. Cl. 257/408

(57) ABSTRACT

A semiconductor device (10) having asymmetric source and drain regions is formed so that either the source or drain region is shorted to an isolated well (22). In one embodiment, the source region includes a source silicide region (42) and a source extension region (28), which are electrically and physically in contact with the well region (22), and the drain region includes a drain silicide region (46), a drain extension region (30) and a deep doped drain region (38). The source and drain regions have a conductivity that is different than that of the isolated well (22) in which they are formed. To prevent the formation of a deep doped source region when the deep doped drain region (38) is formed, a masking layer (34) is patterned to cover the source region during implantation of the deep doped drain region (38).

### FIELD OF THE INVENTION

This invention relates generally to semiconductor devices, and more specifically, to semiconductor devices formed in isolated well regions.

### BACKGROUND OF THE INVENTION

Forming semiconductor devices in isolated wells allows for the application of different voltages on individual wells since they are electrically isolated from each other. The ability to have different well potentials allows for a wider range of circuit design and allows for different memory array architectures. Isolated wells can be implemented on Silicon on Insulator (SOI) or in a bulk silicon substrate. One problem arising from having an isolated well is the susceptibility of the device to undergo destructive breakdown, which is caused by a high well resistance, or floating body. Holes are injected into the substrate by impact ionization near the drain region, resulting in a forward bias at the source-substrate junction. The forward bias causes the threshold voltage to reduce, increasing the drain current, which in turn generates more impact ionization. This positive feedback of hole injection can lead to an undesirable phenomenon known as “snap-back,” which is a substantial increase in the current of the semiconductor device that can ultimately lead to destruction of the semiconductor device.

An electrical contact to the isolated well may be used to overcome the problems discussed above caused by the floating body. For example, in one proposed solution, a well tie is formed adjacent to the source region in a lateral direction. A subsequent silicidation is then used to short the well tie to the source region; however, this added well tie laterally adjacent to the source region increases the area required for forming each semiconductor device, thus increasing overall surface area of the semiconductor die. Therefore, a need exists for providing an electrical connection to an isolated well of the semiconductor device which reduces well resistance and floating body effects without increasing the overall surface area of the semiconductor die.

### BRIEF DESCRIPTION OF THE DRAWINGS

The present invention is illustrated by way of example and not limited by the accompanying figures, in which like references indicate similar elements, and in which:

FIG. 1 illustrates a cross-sectional view of a semiconductor device having a gate stack formed over a semiconductor layer during an implant in accordance with an embodiment of the present invention;

FIGS. 2-3 illustrate a cross-sectional view of the gate stack of FIG. 1 after formation of extension regions in the semiconductor layer and spacers along its sidewalls, in accordance with an embodiment of the present invention;

FIGS. 4-5 illustrate the semiconductor device of FIG. 3 after forming a deep N+/P+ region within the semiconductor layer in accordance with an embodiment of the present invention; and

FIGS. 6-7 illustrates the semiconductor device of FIG. 5 after siliciding the source and drain regions and gate in accordance with an embodiment of the present invention.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION OF THE DRAWINGS

In one embodiment, a semiconductor device having asymmetric source and drain regions is formed so that the source region is shorted to an isolated well region. In one embodiment, a silicide portion at the source region is used to short the extension region to the isolated well region so as to form an electrical contact to both the source and isolated well of the semiconductor device without the need for a separate well tie. The electrical contact is therefore used to provide a same voltage potential to both the source and well of the semiconductor device. This electrical contact, as will be discussed in more detail below, eliminates the floating body effect, reduces well resistance, and prevents transistor “snap back”.

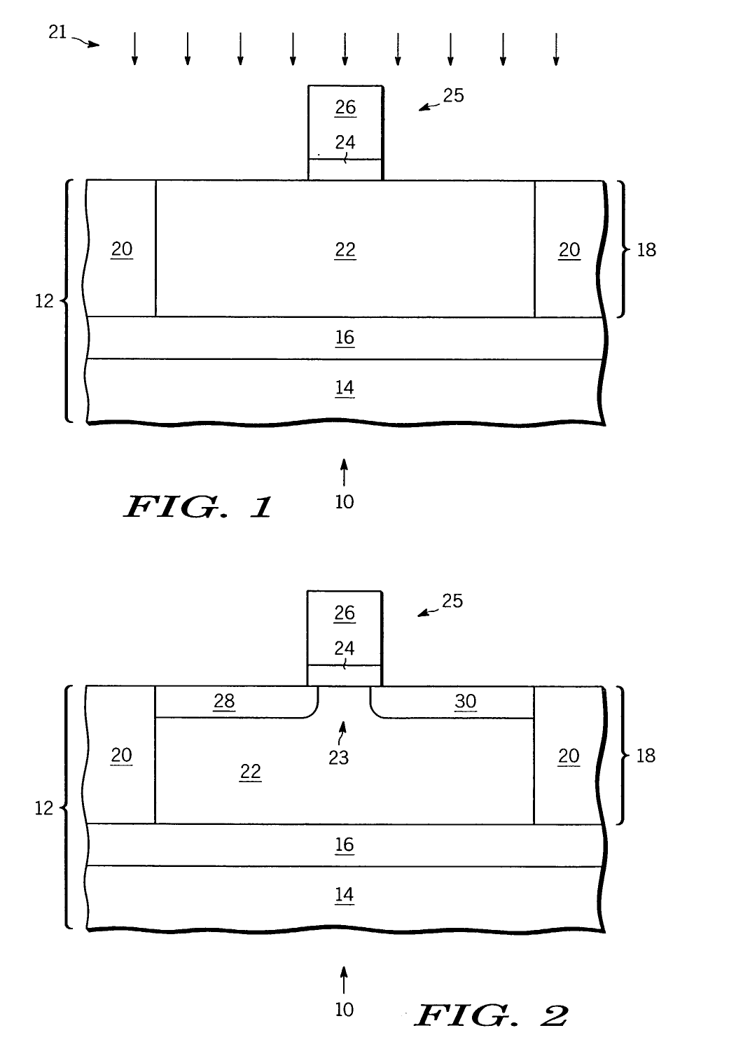

FIG. 1 illustrates a semiconductor device 10 including a semiconductor substrate 12, a dielectric 24, and a gate 26. In the illustrated embodiment, the semiconductor substrate 12 is an SOI substrate having a bottom semiconductor layer 14, a buried insulating layer 16, and a top semiconductor layer 18. In one embodiment, buried insulating layer 16 is a silicon oxide layer and semiconductor layers 14 and 18 may be formed of silicon, germanium, gallium arsenide, or the like. In one embodiment, the top semiconductor layer 18 is a silicon substrate having an isolated well 22. Isolated well 22 is a doped region which may either be a p-type or n-type region, as will be described in more detail below. Also, note that the semiconductor substrate 12 can be any semiconductor-containing substrate such as silicon, silicon germanium, silicon-on-sapphire, the like, or combinations thereof. For example, in one embodiment, semiconductor substrate 12 may be a bulk silicon substrate having isolated well regions.

Top semiconductor layer 18 also includes isolation regions 20 surrounding isolated well 22. Generally, isolation regions 20 are formed using a nonconductive material, such as an oxide. In one embodiment, isolation regions 20 may be shallow trench isolation (STI) regions. In alternate embodiments, such as in bulk silicon substrates where only semiconductor layer 18 would be present without buried insulating layer 16, isolated well 22 may be formed above a buried layer of opposite polarity. In this embodiment, isolation regions 20 would also be located above the buried layer and surrounding isolated well 22. In yet another embodiment, isolated well 22 may be formed by surrounding isolated well 22 with isolation regions 20 having an opposite polarity as compared to the polarity of isolated well 22. In this embodiment, isolation regions 20 would be adjacent to buried layer 16 (e.g. between buried layer 16 and isolated well 22) where buried layer 16 has a same polarity as isolation regions 20.

As shown in FIG. 1, semiconductor device 10 includes a gate stack 25 formed over isolation well 22, where gate stack 25 includes a dielectric 24 formed over isolated well 22 and a gate 26 formed over dielectric 24. In forming gate stack 25, a dielectric layer is blanket deposited or grown over semiconductor substrate 12 using chemical vapor deposition (CVD) or a thermal diffusion process, respectively. Alternatively, the dielectric layer may be formed by physical vapor deposition (PVD), atomic layer deposition (ALD), thermal oxidation, the like or combinations of the above. Then, a conducting layer is deposited over the dielectric layer. Conducting layer may be a polysilicon or metal-containing layer formed by CVD, PVD, ALD, the like or combinations thereof. Using conventional masking and etch processes, the dielectric layer and conducting layer may then be patterned and etched to form the resulting dielectric 24 and gate 26. (Note than in alternate embodiments, each layer of the stack, such as the dielectric layer and conductive layer, may be patterned and etched individually to form the resulting dielectric 24 and gate 26.)

Dielectric 24 can be any insulating material, such as an oxide, nitride, high dielectric constant material, or a combination thereof, and gate 26 can be any conductive material such as polysilicon, metal, or a combination of materials. (Note that dielectric 24 can also be referred to as a patterned insulating layer and gate 26 can also be referred to as a patterned electrode layer.) In the illustrated embodiment, gate stack 25 may be referred to as a logic stack. Alternatively, gate stack 25 may be any type of device stack. For example, it may be a lateral or vertical MOS device used in analog applications. For another example, it may be replaced by a floating gate stack, such as, for example, a non-volatile memory (NVM) stack (not shown) having a tunnel dielectric formed over isolated well 22, a floating gate formed over the tunnel dielectric, a control dielectric formed over the floating gate, and a control gate over the control dielectric.

In forming the NVM stack, a tunnel dielectric layer is formed overlying semiconductor substrate 12 by CVD, PVD, ALD, thermal oxidation, the like, or combination thereof. The tunnel dielectric layer can be any insulating material, such as an oxide (e.g. silicon dioxide), a nitride, an oxynitride, metal oxide, etc. The tunnel dielectric layer is then patterned and etched using conventional processing to form the tunnel dielectric of the NVM stack overlying isolated well 22 (where the tunnel dielectric is located in a similar location as dielectric 24 of gate stack 25 illustrated in FIG. 1).

A floating gate layer is then formed over the semiconductor substrate 12 and the tunnel dielectric by CVD, PVD, ALD, the like, or combinations thereof. In one embodiment, the floating gate layer may be a nitride containing material, such as silicon nitride. Alternatively, floating gate layer may be any conductive material, such as a polygate, polysilicon, metal, or the like. In yet another embodiment, floating gate layer may be a plurality of nanocrystals (i.e. discrete storage elements) such as in a nanocrystal NVM device. The floating gate layer is then patterned and etched using conventional processing to form the floating gate of the NVM stack overlying the tunnel dielectric

A control dielectric layer is then formed over the semiconductor substrate 12 and the floating gate by CVD, PVD, ALD, thermal oxidation, the like, or combinations thereof. The control dielectric layer is then patterned and etched using conventional processing to form the control dielectric of the NVM stack overlying the floating gate. Note that the control dielectric is optional and may not be formed in all NVM devices. If present, the control dielectric layer can be any insulating material, such as an oxide (e.g. silicon dioxide), nitride, metal oxide, high dielectric constant material (i.e. a material having a dielectric constant of greater than approximately 4 and less than approximately 15), the like, or combinations thereof.

A control gate layer is then formed over the semiconductor substrate 12 and the control dielectric by CVD, PVD, ALD, the like, or combinations thereof. Control gate layer may be any conductive material, such as polysilicon or a metal-containing material. Using conventional masking and etch processes, the control gate layer is patterned and etched to form the control gate of the NVM stack overlying the control dielectric. (Note that in alternate embodiments, rather than patterning and etching each layer of the NVM stack separately, combination of layers or all the layers may be patterned and etched using a same pattern and etch process in order to reduce processing steps required to form the resulting NVM stack.)

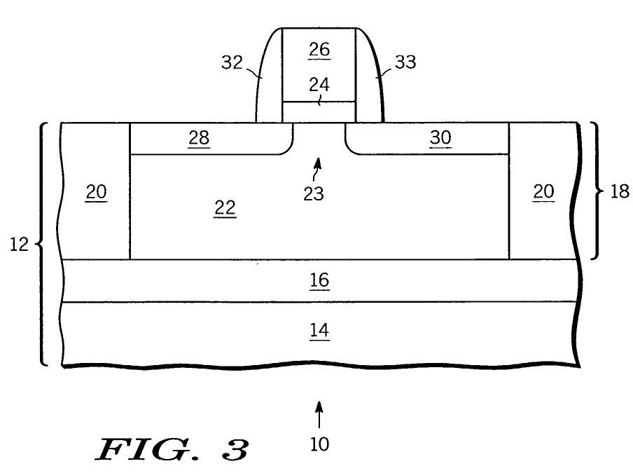

Referring to FIG. 1, after forming gate stack 25 (or a logic stack, NVM stack, etc.), an implant 21 is performed. Implant 21 is used to form extension regions for both a source and a drain in semiconductor device 10. Following the implant, a conventional anneal is performed. FIG. 2 illustrates the resulting semiconductor device 10 having extension region 28 formed for the source and extension region 30 formed for the drain. In one embodiment, the resulting extension regions 28 and 30 have a depth between 20 Angstroms and 2000 Angstroms. Preferably, extension regions 28 and 30 have a depth between 50 and 1000 Angstroms, and most preferably, have a depth between 100 and 300 Angstroms. Also note that a channel region 23 is formed between extension regions 28 and 30, below dielectric 24.

In the case of isolated well 22 being an isolated p-well, extension regions 28 and 30 are n-type extensions, which may be formed by a low arsenic energy implantation with an energy of between 1 and 10 KeV. For example, an arsenic ion implant with an energy of 3 KeV and a dosage of 2e15/cm² may be used to form n-type extensions in an isolated p-well. However, alternate embodiments may use different implant species, different concentrations, and different energies for forming extension regions 28 and 30 in isolated well 22. For example, the species of extension regions 38 and 30 can also include phosphorous, antimony, or the like.

In the case of isolated well 22 being an isolated n-well, extension regions 28 and 30 are p-type extensions, which may be formed by a low boron energy implantation with an energy of between 1 and 50 KeV. For example, a boron ion implant with an energy of 10 KeV and a dosage of 2e15/cm² may be used to form p-type extensions in an isolated n-well. However, alternate embodiments may use different implant species, different concentrations, and different energies for forming extension regions 28 and 30 in isolated well 22. For example, the species of extension regions 38 and 30 can also include indium, gallium, or the like.

FIG. 3 illustrates semiconductor device 10 after formation of spacers 32 and 33. For example, after forming extension regions 28 and 30, an insulating layer (not shown) is formed over the semiconductor device 10 by CVD, PVD, the like or combinations thereof, and anisotropically etched to form spacers 32 and 33 adjacent sidewalls of the gate 26 and dielectric 24. Generally, spacers 32 and 33 are formed with a nitride material, such as silicon nitride. However, alternate embodiments may not include an etching process in forming spacers 32 and 33. For example, if spacers 32 and 33 are formed by heavy oxidation of the polysilicon gate, spacers 32 and 33 may not be formed by an anisotropic etch. Alternatively, the spacer can be a combination of polysilicon oxidation and anisotropic etch processes. If the process technology allows, such as metal gate or poly thin film transistor technology, spacers 32 and 33 may not be present.

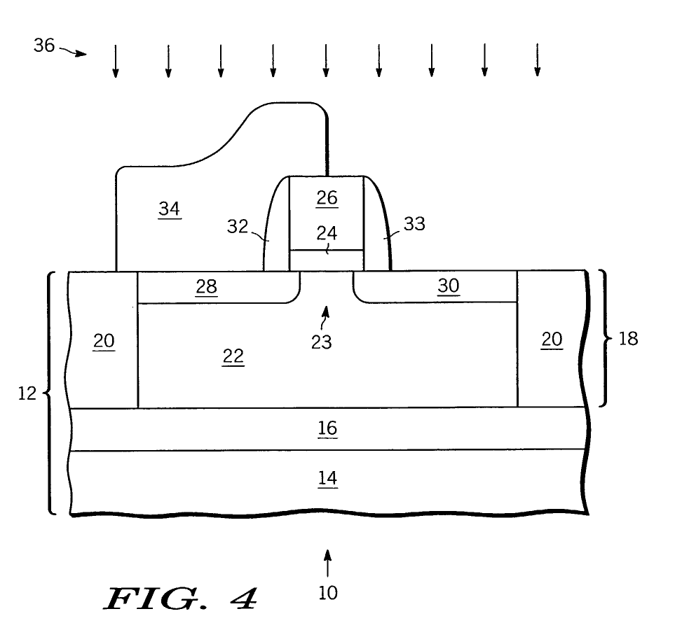

FIG. 4 illustrates semiconductor device 10 after forming and patterning a masking layer to form a patterned masking layer 34 overlying extension region 28 and extending over portions of gate 26 and portions of isolation region 20 adjacent to extension region 28. (Note that in one embodiment, patterned masking layer 34 may be a photo resist layer, which may be formed and patterned according to conventional processing methods.) Therefore, patterned masking layer 34 masks at least the exposed portions of extension region 28 such that the subsequent implantation (as indicated by arrows 36 in FIG. 4) does not affect extension region 28. That is, patterned masking layer 34 exposes extension region 30 such that extension region 30, and not extension 28, is doped as a result of implant 36. In this manner, a deeper implant is achieved for extension 30 (corresponding to the drain of semiconductor device 10) than for extension region 28 (corresponding to the source of semiconductor device 10). As will be seen, this will result in semiconductor device 10 having asymmetrical source and drain regions which allows for the source region to be shorted to isolated well 22 in a subsequent salicidation process.

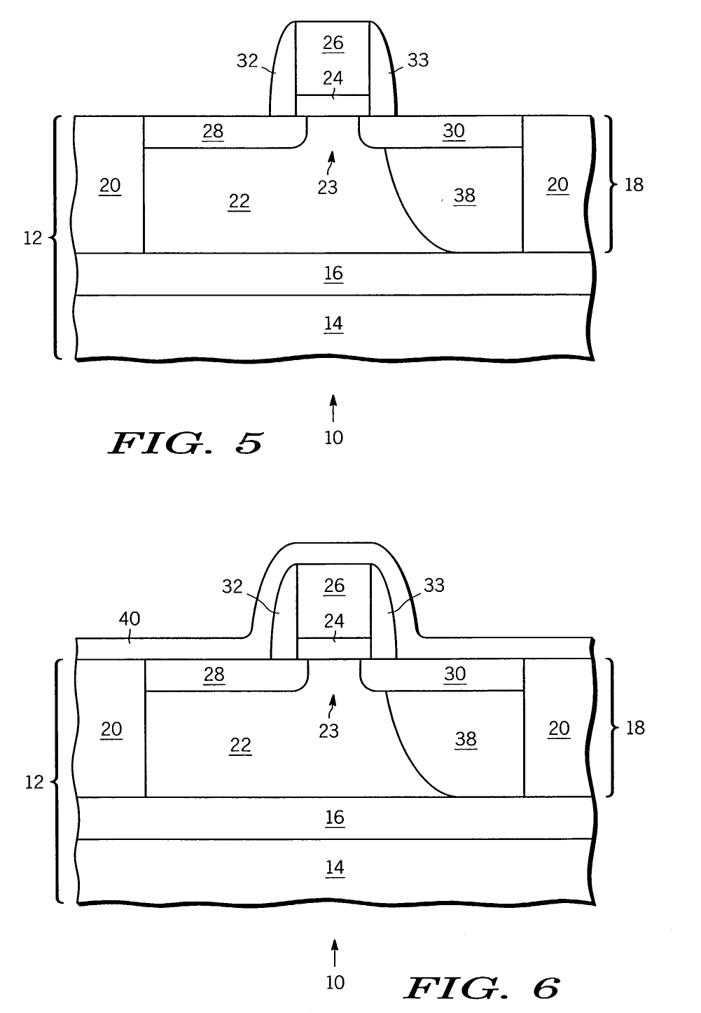

FIG. 5 illustrates semiconductor device 10 having an N+/P+ region 38 resulting from implant 36 of FIG. 4. (Note that the terminology of “N+/P+” indicates that region 38 may be either N+ or P+ depending on the polarity of isolated well 22.) Therefore, FIG. 5 illustrates a deep drain region (a combination of extension 30 and N+/P+ region 38) and a shallow source region 28 where the deep drain region extends deeper into isolated well 22 as compared to the shallow source region. In the illustrated embodiment, N+/P+ region 38 extends completely through isolated well 22 to buried insulating layer 16; however, in alternate embodiments, N+/P+ region 38 may not extend completely through isolated well 22. In one embodiment, N+/P+ region 38 has a depth of 500 to 5000 Angstroms, and preferably, N+/P+ region 38 may have a depth of 1000 to 3000 Angstroms.

In the case of isolated well 22 being an isolated p-well, the implant of FIG. 4 results in a deep N+ region 38, which, in combination with n-type extension 30, forms a deep drain region, while n-type extension 28 forms a shallow source n-type region. In one embodiment, the species of implant 36 may include arsenic, phosphorous, antimony, or the like, and implant 36 may be performed at an energy of 1 KeV to 60 KeV. For example, in one embodiment, an arsenic ionic implant having a concentration of 5e14/cm² at an energy of 30 KeV may be used to form N+ region 38. Alternate embodiments may use different species, concentrations, and energies to form N+ region 38.

In the case of isolated well 22 being an isolated n-well, the implant of FIG. 4 results in a deep P+ region 38, which, in combination with p-type extension 30, forms a deep drain region, while p-type extension 28 forms a shallow p-type source region. In one embodiment, the species of implant 36 may include boron, gallium, indium, or the like, and implant 36 may be performed at an energy of 1 KeV to 60 KeV. For example, in one embodiment, a boron ionic implant having a concentration of 5e14/cm² at an energy of 5 KeV may be used to form P+ region 38. Alternate embodiments may use different species, concentrations, and energies to form P+ region 38.

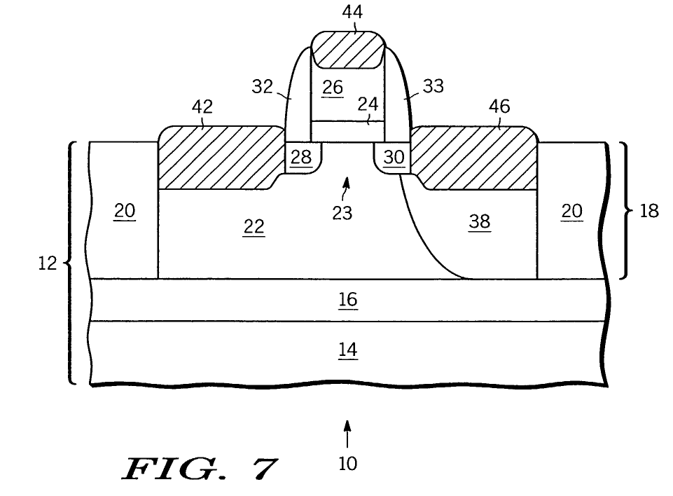

FIG. 6 illustrates semiconductor device 10 after formation of a refractory metal layer 40 overlying semiconductor device 10. In one embodiment, refractory metal layer 40 includes tungsten, cobalt, titanium, or the like, and may be formed by CVD, PVD, ALD, or the like. FIG. 7 illustrates semiconductor device 10 after a rapid thermal anneal (RTA) salicide process and a subsequent cleaning processing. That is, after formation of refractory metal layer 40 (as shown in FIG. 6), an RTA salicide process is performed which forms metal silicide portions (or regions) 42, 44, and 46. (The remainder of the refractory metal layer 40 which does not react during the RTA salicidation process is then removed during a cleaning process, as known in the art.) Silicide portion 44 is formed at the top of gate 26. The salicidation process consumes silicon; therefore, a portion of gate 26 gets consumed and produces a metal silicide layer 44, which is highly conductive. Therefore, slicide portion 44 extends into and above gate 26. Silicide portion 46 is formed at the top of the drain region 38 located at the top of semiconductor layer 18, adjacent to spacer 33. That is, silicide portion 46 consumes the exposed portion of extension region 30 and extends partially into N+/P+ region 38. Note that a portion of extension region 30 which underlies spacer 33 and dielectric 24 remains. Note also that silicide portion 46 does not consume all of N+/P+ region 38 such that silicide portion 46 remains electrically isolated from isolated well 22. Therefore, suicide portion 44 provides an electrical contact to the control electrode (also referred to as the gate electrode) of semiconductor device 10, and silicide portion 46 provides an electrical contact to a first current electrode (also referred to as a drain electrode) of semiconductor device 10.

Silicide portion 42 is formed at the exposed portion of extension region 28 located at the top of semiconductor layer 18, adjacent to spacer 32. However, the formation of silicide portion 42 consumes all of the exposed portion of extension region 28, leaving only a portion of extension region 28 which underlies spacer 32 and dielectric 24. Therefore, silicide portion 42 provides an electrical contact to a second current electrode (also referred to as a source electrode) of semiconductor device 10. However, since a deep N+/P+ region such as N+/P+ region 38 is not present in the source region of semiconductor device 10, silicide portion 42 forms a short between extension region 28 and isolated well 22. Therefore, in semiconductor device 10, isolated well 22 is no longer a floating body. Instead, it is shorted to the source electrode of semiconductor device 10 via silicide portion 42. Thus, silicide portion 42 is laterally disposed from spacer 32 (if present), and both silicide portion 42 and extension region 28 are in electrical and physical contact with isolated well 22. Therefore, in one embodiment, semiconductor device 10 includes only silicide portion 42 and extension region 28 as its source electrode, without requiring an additional deep N+/P+ region.

Formation of suicide portion 42 should therefore be performed such that silicide portion 42 consumes all of the exposed portions of extension region 28 so as to short the source of semiconductor device 10 to isolated well 22. Alternatively, silicide portion 42 may not entirely consume the exposed portion of extension region 28, but may consume a sufficient amount to create a large leakage current in the junction between remaining extension region 28 and isolated well 22. In this embodiment, silicide portion 42 is still in electrical contact with isolated well 22 but may not be in physical contact with isolated well 22. Formation of silicide portion 46 should be performed such that silicide portion 46 does not consume all of N+/P+ region 38 so as to ensure that silicide portion 46 (the drain of semiconductor device 10) is electrically isolated from isolated well 22.

Note that the formation of silicide portion 42 without an N+/P+ region (such as N+/P+ region 38) results in an electrical contact to both the source electrode and body (i.e. isolated well 22) of semiconductor device 10 without requiring a separate well tie, thus decreasing the surface area required for forming semiconductor device 10. This also eliminates the floating body effect and latch up since the body is now shorted to the source electrode. Furthermore, because the source and well is always at the same potential, the parasitic bipolar device will never turn on, thus preventing transistor “snap back”. Also, in the illustrated embodiment, silicide portion 42 (which provides the source and well connection) reduces the well resistance because it is adjacent to the well.

Note that further processing of semiconductor device 10 may be performed, as known in the art, to form a substantially completed semiconductor device. For example, after forming silicide portions 42, 44, and 46, processing is continued as known to one skilled in the art by depositing an interlevel dielectric (ILD), forming metal interconnects, and forming contacts between metal interconnects and the gate electrode 44, and source/drain electrodes 42 and 46 to form a finished device. In one embodiment, semiconductor device 10 can be used as part of a logic circuit or if gate stack 25 is replaced with an NVM stack, semiconductor device 10 may be used in an NVM memory (either stand alone or embedded with other logic circuits).

In one embodiment, a semiconductor device such as semiconductor device 10 can be used as pull-up and pull-down transistors for a logic gate. For example, for a logic inverter gate, the PMOS pull-up transistor can have a source and well electrode (provided by silicided portion 42) shorted to Vdd. Similarly, for the NMOS pull-down transistor can have a source and well electrode (provided by silicided portion 42) shorted to Vss. (Note that generally, Vdd is a first power supply voltage that is higher than Vss, which is a second power supply voltage. For example, in one embodiment, Vss is ground, and Vdd is the supply voltage for the semiconductor device.) Alternatively, a semiconductor device such as semiconductor device 10 can be used as the pull-up and pull-down devices of a dynamic clocked logic gate.

In another embodiment, an NMOS transistor (like semiconductor device 10) may be used as a low side driver in power applications. In this embodiment, the load is connected to the drain electrode and the source is tied to the isolated well by silicide portion 42. The proximity of the well contact with respect to the channel region reduces the well resistance, providing a good immunity to snap back.

In one embodiment using a Uniform Channel Program Erase (UCPE) NVM array, an isolated well can be used for selecting a bitline. Therefore, semiconductor devices such as semiconductor device 10 may be used to provide a contact to the isolated well (which, as illustrated in FIG. 7, is shorted to the source electrode). This prevents the need for a separate well tie far away from the array bitcells, thus reducing the well resistance and the area required for forming the NVM array. Note that during erase, read, and programming of a UCPE NVM array, the source and well are always at the same potential, thus allowing semiconductor device 10 (which provides a shorted source and well contact) to be used for implementing a UCPE NVM array.

Although the invention has been described with respect to specific conductivity types, skilled artisans appreciate that conductivity types may be reversed. For example, the source and drains and extensions may be p-type or n-type, depending on the polarity of the isolated well, in order to form either p-type or n-type semiconductor devices. Also, note that, as used herein, a control electrode corresponds to the gate electrode of semiconductor device 10, and that the first current electrode correspond to either the source or drain of semiconductor device 10, and the second current electrode corresponds to the other of the source or drain of semiconductor device 10. Therefore, it should be understood that either the first current electrode or the second current electrode of semiconductor device 10 may be shorted to the isolated well 22 via a silicide portion. However, generally, the current electrode that is shorted to the well is referred to as the source because the conducting carrier is generated at the source node when the gate voltage is above a certain threshold during normal operations of a metal-oxide-semiconductor transistor (MOS). Also, in alternate embodiments, other materials and processing steps may be used to form semiconductor device 10; those described above have only been provided as examples.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

1. A semiconductor device comprising:
a semiconductor substrate having a first doped region;
an insulating layer over the semiconductor substrate, wherein the insulating layer has a first side and a second side opposite the first side
a first spacer adjacent the first side of the insulating layer;
a second spacer adjacent the second side of the insulating layer;
a first silicide region laterally disposed from the first spacer and in electrical contact with the first doped region; and
a first extension region under the first spacer, wherein the first extension region is in physical and electrical contact with the first silicide region.

2. The semiconductor device of claim 1 further comprising a second silicide region adjacent the second spacer.

3. The semiconductor device of claim 2 further comprising a second doped region under the second silicide region and the second spacer and in contact with the second silicide region, wherein the first doped region has a first conductivity and the second doped region has a second conductivity that is different than the first conductivity.

4. The semiconductor device of claim 3 further comprising a second extension region under the second spacer and adjacent to the second silicide region.

5. The semiconductor device of claim 4 wherein the first extension region and the second extension region are the second conductivity.

6. The semiconductor device of claim 1 wherein the semiconductor substrate is a silicon-on-insulator (SOI) substrate.

7. The semiconductor device of claim 1 wherein the first doped region is an isolated well region.

8. The semiconductor device of claim 1 wherein a first current electrode consists of the first silicide region and the first extension region.

9. The semiconductor device of claim 1 wherein the first extension region is in physical and electrical contact with the first doped region.

10. A semiconductor device comprising:
a semiconductor substrate having a first doped region;
a device stack comprising a first insulating layer and an electrode layer, wherein the device stack is over the semiconductor substrate, has a first side and a second side opposite the first side;
a first silicide region laterally disposed from the first side of the device stack and in physical and electrical contact with the first doped region;
a first extension region adjacent the first silicide region and in physical and electrical contact with the first doped region and the first silicide region;
a second suicide region laterally disposed from the second side of the device stack; and
a second doped region in the first doped region, wherein the second doped region is under the second silicide region, and wherein the first doped region has a first conductivity and the second doped region has a second conductivity that is different than the first conductivity.

11. The structure of 9 further comprising:
a first spacer adjacent the first side of the device stack;
a second spacer adjacent the second side of the device stack, and wherein the first extension region is under the first spacer.

12. The semiconductor device of 11 wherein:
the semiconductor substrate comprises a second insulating layer and a semiconductor layer over the second insulating layer; and
the first doped region is in the semiconductor layer and in contact with the second insulating layer.

13. The semiconductor device of claim 12 further comprising isolation regions in the semiconductor layer laterally disposed from the first doped region and in contact with the second insulating layer.

14. The semiconductor device of claim 11 wherein the second silicide region is adjacent the second spacer.

15. The semiconductor device of claim 14 wherein at least a portion of the first extension region is under the device stack.

16. The semiconductor device of claim 15 further comprising a second extension region adjacent to the second silicide region, wherein at least a portion of the second extension region is under the device stack.

17. The semiconductor device of claim 16 wherein the first extension region and the second extension region have the second conductivity.

18. The semiconductor device of claim 10 wherein a first current electrode consists of the first silicide region and the first extension region.

19. A method for forming a semiconductor device:
providing a semiconductor substrate having a first doped region;
forming an insulating layer over the semiconductor substrate;
patterning the insulating layer;
forming an electrode layer over the insulating layer;
patterning the electrode layer;
forming a second doped region in the first doped region, wherein a portion of the second doped region is under the patterned insulating layer;
forming a third doped region in the first doped region, wherein a portion of the third doped region is under the patterned insulating layer;
forming a patterned photo resist over the second doped region; and
implanting a species into the first doped region while the patterned photo resist is over the second doped region.

20. The method of claim 19, further comprising:
forming a first suicide region from at least a portion of the second doped region; and
forming a second silicide region from at least a portion of the second extension region.
